(19) United States
(12) Patent Application Publication
(10) Pub. No.: US 2020/0341372 A1
(43) Pub. Date: Oct. 29, 2020

(54) REPLICATION DEVICE AND METHOD FOR REPRODUCING A STRUCTURE ON A SUBSTRATE

(71) Applicant: SUSS MicroTec Lithography GmbH, Garching (DE)

(72) Inventor: Christian MAY, Garching (DE)

(21) Appl. No.: 16/862,179

(22) Filed: Apr. 29, 2020

(30) Foreign Application Priority Data
Apr. 29, 2019 (NL) 2023022

(51) Int. Cl. G03F 7/00; G03F 7/20

(52) U.S. Cl. CPC G03F 7/0002; G03F 7/20

(57) ABSTRACT

Replication device for producing at least one of nanostructured and microstructured components with two assemblies that are moveable in relation to each other, wherein the first assembly has a chuck for receiving a substrate and a second assembly a holder for an imprint structure, wherein the assemblies are moveable relative to each other between an imprint position and a loading position, and wherein at least a sealing lip is located on one of the two assemblies, the sealing lip facing the other one of the two assemblies and contacting the other one of the two assemblies in the imprint position and radially surrounding at least one of the chuck and the holder, wherein a sealed overpressure chamber between the two assemblies is limited by the sealing lip in the imprint position. Further, also a method for reproducing a structure on a substrate is shown.

### FIELD OF THE DISCLOSURE

The disclosure relates to a replication device for producing nanostructured and/or microstructured components and a method for reproducing a structure on a substrate.

### BACKGROUND

Replication devices for producing nanostructured and/or microstructured components are well-known. For example, a structure is reproduced onto a substrate that is coated with an imprint material by means of an imprint structure.

Before coating the substrate with an imprint material, the substrate is moved against an imprint structure in order to parallelize the substrate relative to the imprint structure. This is necessary as a width of the substrate can be non-uniform, in particular the width can decrease from one peripheral portion to another peripheral portion. Even the imprint structure itself can be inclined as a result of tolerances. Such a parallelization is also referred to as wedge error compensation.

The replication device has a wedge error compensation head with a stationary part and a moveable part for this purpose, wherein the substrate is mounted on the moveable part. The part mounted moveably can be locked in place relative to the stationary part at a defined angle after the parallelization. Subsequently, the substrate is coated and moved once again against the imprint structure. As a result of the previous parallelization, the imprint structure can be immersed in the imprint material exactly vertically so that the structuring takes places particularly uniformly.

However, adhesive forces can occur between the substrate and the imprint structure when parallelizing the substrate on the imprint structure so that the substrate briefly remains stuck to the imprint structure while the wedge error compensation head is moving down and the separation of the substrate from the imprint structure lags behind the movement of the wedge error compensation head, thus losing the previously attained wedge error compensation. As a result, the accuracy of the structuring is impaired.

### SUMMARY

Thus, there is a need to provide an improved replication device with which the production accuracy in producing nanostructured and/or microstructured components can be improved. Moreover, it is an object of the disclosure to determine an optimized method for reproducing a structure on a substrate.

This object is solved according to the disclosure by means of a replication device for producing nanostructured and/or microstructured components with two assemblies that can be moved in relation to each other, wherein the first assembly comprises a chuck for receiving a substrate and a second assembly a holder for an imprint structure, in particular a stamp. The assemblies are moveable between an imprint position and a loading position relative to each other, wherein at least a sealing lip is located on one of the two assemblies, said sealing lip facing the other one of the two assemblies and contacting the other one of the two assemblies in the imprint position and radially surrounding the chuck and/or the holder, wherein a sealed overpressure chamber between the two assemblies is limited by the sealing lip in the imprint position.

The first and the second assemblies can be moved along a central axis toward and away from each other. For example, both assemblies are mounted moveably. However, one of the two assemblies, in particular the first assembly, is preferably mounted moveably and the other one of the two assemblies, in particular the second assembly, is mounted stationarily. Thus, it is only necessary to provide a drive for one of the two assemblies, thus simplifying the design of the replication device.

A defined pressure can be applied in the overpressure chamber as a result of the seal, in particular overpressure. This pressure is used to separate the substrate from the imprint structure. This can be achieved by forcing the substrate and the imprint structure actively apart from each other through the application of overpressure. Thus, a previously attained parallelization, in particular a wedge error compensation, can be maintained so that a subsequent production process can take place with a particularly high degree of accuracy.

For example, a set wedge error compensation can be maintained over a longer production period, in particular for the production of at least two nanostructured and/or microstructured components. This is referred to as a “global wedge error compensation”. In this regard, it is important that the wedge error compensation remains precise so that all components can be produced with the same quality.

Alternatively, a wedge error compensation can be reset for each substrate.

The sealing lip surrounds the chuck and/or the holder completely radially in order to reliably seal the overpressure chamber.

The sealing lip is preferably inflatable. The volume of the sealing lip can therefore be varied, in particular increased. Thus, a sealing the overpressure chamber can be carried out particularly reliably. If the volume of the sealing lip is increased while the assemblies are in the imprint position, the assemblies are forced apart by the sealing lip. In addition to the overpressure, the sealing lip can thus actively help to generate a separation force that forces the two assemblies apart.

The height of the sealing lip can vary in the inflated state in the circumferential direction of the sealing lip. This means that that the profile of the sealing lip is not constant. Thus, a detachment of the sealing lip can be simplified when moving the assemblies out of the imprint structure. In this case, the sealing lip is namely not separated along its complete circumference uniformly, but rather it is detached gradually, first at the points with the least height and then at the points with the greatest height. Preferably, the height of the sealing lip in the circumferential direction initially increases continuously starting from the lowest point until a highest point and then decreases again. Thus, there are no steps in the sealing lip.

The sealing lip is for example annular or portal-shaped seen in top view of the corresponding assembly. Such geometries are easily producible. In addition, the geometry of the sealing lip can be adapted to the geometry of the first assembly, in particular the chuck.

According to an embodiment, two sealing lips may be provided that are inflatable separately from each other, wherein one of the sealing lips surrounds the other radially, in particular completely. In this way, two sealed chambers that are separated from each other can be formed, thus optimizing the imprint process. The sealing lips can vary in their contours and/or in their heights. Alternatively or additionally, one of the sealing lips can have a varying height and the other sealing lip can have a constant height.

The inner sealing lip of both sealing lips is preferably formed in such a way that a substrate positioned on a chuck is positioned completely within the first chamber.

According to an embodiment, a first chamber can be formed by means of the inner sealing lip and a second chamber by means of the outer sealing lip, wherein the first chamber is a vacuum chamber and the second chamber the overpressure chamber. By means of a vacuum chamber, the substrate is drawn to the stamp, thus achieving a particularly good alignment of the substrate on the imprint structure. In addition, the vacuum can be used to degas the imprint material in an imprint process as well as to remove small bubbles from the imprint material and between the imprint structure, the imprint material and the substrate.

The overpressure chamber is used to separate the substrate from the imprint structure as previously described.

For example, the use of the first sealing lip results in an annular, particularly rotationally symmetrical pressure chamber seen in top view and the use of the second sealing lip an axially symmetrical, in particular portal-shaped pressure chamber seen in top view.

The imprint structure is for example formed by a silicon-based polymer, in particular polydimethylsiloxane. Other polymer materials are however also conceivable. In particular, the imprint structure can be sticky and/or rippled.

The polymer can be located on a glass plate and thus form a stamp. Alternatively, the polymer can be applied to a sheet material which is located on the glass plate. The sheet material can be firmly pressed on the glass plate by the overpressure in the overpressure chamber. The imprint structure has sufficient stability as a result of the glass plate and does not bend when the substrate is moved against the imprint structure. The polymer itself is however elastic. This is advantageous as when applying overpressure, the polymer material can be compressed to a certain extent by the overpressure, whereby a detachment of the imprint structure from the substrate also occurs, in particular an active detachment.

The first assembly can form, for the purpose of wedge error compensation, a wedge error compensation head comprising a stationary part and a moving part. The moving part, which contains in particular the chuck for receiving the substrate, can be fixed in place at a specific angle relative to the stationary part when the wedge error compensation is set.

In addition, the replication device comprises for example a pressure source for generating overpressure in the sealing lip and/or the overpressure chamber. Thus, sufficiently high overpressure can be generated in the sealing lip as required in order to form the overpressure chamber and/or sufficiently high pressure may be generated in the overpressure chamber in order to achieve active movement of the first assembly and the second assembly relative to each other and to ensure uniform detachment of the substrate from the imprint structure without losing the wedge error compensation.

Moreover, an exposure device can be provided for curing microstructures and/or nanostructures formed on a substrate. Such an exposure device is for example suitable for exposing microstructuring and/or nanostructuring to ultraviolet light, in particular to light of a wavelength of 250 nm to 459 nm, preferably 365 nm.

Furthermore, this object is solved according to the disclosure by a method for reproducing a structure on a substrate, in particular using a replication device designed as previously described comprising the following steps:
placing a substrate on a first assembly of the replication device, in particular on a chuck, and placing an imprint structure on a second assembly of the replication device, in particular a holder;
moving the assemblies relative to each other from a loading position into an imprint position, in particular after the substrate and the imprint structure have been placed in the replication device, wherein a surface of the substrate facing the imprint surface or a coating of the substrate comes into in contact with imprint structure all over in the imprint position; and
actively moving the first assembly and the second assembly, in particular of both assemblies after the substrate has been brought into contact with the imprint structure, away from each other through the application of a separation force.

A movement in the imprint position can be carried out for the purpose of compensating the wedge error or placing structures in a coating. If the substrate is still uncoated during a movement into the imprint position, in particular no imprint material is applied to the substrate, the movement into the imprint position serves the purpose of wedge error compensation. If the substrate is already coated with an imprint material during a movement into the imprint position, the imprint material is structured by the imprint structure upon achieving the imprint position.

The imprint material is for example an epoxy resin. However, the imprint material can also be a thin layer of an alternative material, that for example is applied by coating, in particular by means of a coating device.

The active movement by means of a separation force occurs particularly only out of the imprint position, but not into the loading position. In particular, the separation force serves to separate the uncoated substrate from an imprint structure without losing a previously attained wedge error compensation or in order to separate a coated substrate particularly easily and reliably from the imprint structure.

The first and second assemblies comprise for example a central axis, wherein the central axis of the first and second assemblies are aligned parallel to each other, in particular coaxially to each other. The movement of the assemblies preferably occurs in a direction along the central axis.

According to a further method step, an inflatable sealing lip of the replication device that surrounds the substrate radially can be inflated when the first assembly is in the imprint position so that a sealed overpressure chamber is formed. The formation of a sealed overpressure chamber makes it possible to create overpressure in an area surrounding the substrate or the imprint structure. This overpressure can generate the separation force which presses the two assemblies apart.

Furthermore, the first assembly and the second assembly can be pressed apart when inflating the sealing lip so that the sealing lip generates the separation force. This means that an active movement of both assembles relative to each other is achieved by inflating the sealing lip, in particular from the imprint position.

Both inflating the sealing lip and generating overpressure facilitate the detachment of the substrate from the imprint structure, namely in the coated and uncoated state of the substrate.

Preferably, the substrate is initially placed in an uncoated state on the replication device, in particular on the chuck, and moved together with the first assembly into the imprint position in order to parallelize the substrate relative to the imprint structure. In other words, a wedge error compensation is implemented. The assemblies are initially brought into the loading position in which the assemblies are spaced apart relative to each other in order to able to place the substrate.

According to a further method step, the substrate and/or the imprint structure are coated with an imprint material and then moved in a coated state together with the first assembly into the imprint position to structure the coating by means of the imprint structure.

The first assembly is preferably brought into the loading position in order to coat the substrate with the imprint material.

Then, i.e. after the structuring, the imprint material can be exposed to light in the imprint position, in particular ultraviolet light. As a result, the imprint material is cured.

After the exposure, the substrate can be completed with the microstructuring and/or nanostructuring and can be removed from the replication device, in particular after the assemblies have been moved into the loading position again.

Overpressure is generated in the imprint position in the sealed overpressure chamber, particularly after the curing of the imprint material, by means of an overpressure source in order to attain the active movement so that the separation force is generated by the overpressure source in connection with the sealing lip.

In the case of a coated substrate, the profitability of the production is greatly increased by the separation force. If the substrate is coated, in particular if the imprint material is already cured, the adhesive forces between the substrate and the imprint structure can be so strong that the substrate had to be separated from the imprint structure previously by means of an auxiliary tool. For this purpose, the imprint structure had to be removed mechanically from the replication device in order to make it possible to access the imprint structure or the substrate by means of an auxiliary tool. This step can be eliminated by means of the method according to the disclosure. Furthermore, the separation force can prevent the imprint structure from breaking, in particular a polymer component of the imprint structure, for example by compressing the imprint structure, in particular the polymer material, at least in part through overpressure.

Preferably, the overpressure is sufficiently great to force the imprint structure and the substrate apart if the substrate is uncoated or coated. As the adhesive forces occurring with a coated substrate are stronger than with an uncoated substrate, the overpressure generated in the overpressure chamber is greater when a coated substrate is to be detached than when an uncoated substrate is to be detached. For example, the overpressure to detach a coated substrate can amount to twice or triple the overpressure when detaching an uncoated substrate.

In the uncoated state, the substrate can be moved repeatedly from the loading position into the imprint position, in particular though repeated inflation and at least partial deflation of the sealing lip and/or the overpressure chamber. In this way, a more precise alignment of the substrate on the imprint structure is possible, thus a more precise wedge error compensation. For example, the substrate is moved two or three times in the uncoated state into the imprint position.

In the case of the uncoated substrate being moved repeatedly from the loading position into the imprint position, the substrate can be aligned each time on the imprint structure with a contact force of differing strength, in particular with a contact force that decreases with each repeated alignment. The contact force is the force with which the substrate is pressed against the imprint structure.

The contact force can be set by moving the first and second assemblies toward each other with a defined force and/or for a defined travel. The smaller the contact force is, the smaller the adhesive forces are that occur between the substrate and the imprint structure. Friction between the substrate and the imprint structure is also reduced. Therefore, in the case of repeated alignments, a wedge error compensation can be carried out with particularly high precision with less contact force in each case as in the previous alignment as it is less probable in the case of weaker adhesive forces that the previously attained wedge error compensation is lost.

A moveable part of the first assembly, i.e. the wedge error compensation head, of the replication device is locked in place before both assemblies are actively moved relative to each other. This prevents the moveable part of the first assembly moving from the imprint position into the loading position and vice versa relative to the stationary part of the first assembly when moving assemblies. It is therefore possible to maintain a previously set wedge error compensation.

In the case of particularly strong adhesion of the substrate to the imprint structure after the structuring in the case of complete or partial curing by means of exposure or otherwise, a set wedge error compensation can be cancelled, in particular by removing the locking of the wedge error compensation head. In this case, the wedge error compensation must be reset each time after producing a component, i.e. a “global wedge error compensation” is not possible.

Thus, two wedge error compensation methods (WEC) are basically possible:

A global wedge error compensation which is maintained over a longer process period and an individual wedge error compensation which must be implemented anew when processing each new substrate.

The disclosure uses both methods at different points in the process. In either case, the method is improved by the presence of the overpressure chamber.

On the one hand, the wedge error compensation can be improved by the overpressure in the overpressure chamber.

On the other hand, after a wedge error compensation has been carried out, the set wedge error compensation can be maintained during the separation from the imprint structure and for loading with a substrate.

Furthermore, the substrate can be separated from the imprint structure by means of the overpressure after the process has been carried out, i.e. after curing the imprint material, either in the case of a weak adhesive force with the possibility of retaining the wedge error compensation as a global wedge error compensation or in the case of a strong adhesive force only for the purposes of separation using the function of the wedge error compensation, in particular by deactivating the locking.

Instead of a substrate without an imprint material that is coated and processed later with an imprint material, a dummy substrate can also be used to implement the wedge error compensation. Subsequently, several substrates can be produced without implementing another wedge error compensation in each case.

According to another variant type, pressure in the overpressure chamber is regulated in the imprint position in order to keep a constant gap between the substrate and the imprint structure, in particular during the imprinting of a structure and/or during the exposure. In this way, capillary forces between the substrate and the imprint structure can be counteracted. Such capillary forces occur if the substrate is coated with an imprint material that is not yet or not completely cured and the substrate is positioned close to the imprint structure or contacts the imprint structure. The capillary forces cause the substrate to be drawn towards the imprint structure.

If there are two sealing lips, the first sealing lip of the replication device can be initially inflated and the sealing lip can be deflated at a later time and another sealing lip that is different from the first sealing lip can be inflated. Owing to the differing geometries of the sealing lips, the use of one of the two sealing lips may be advantageous depending on the situation.

For example, a first chamber is formed using the first sealing lip and the second chamber is formed using the second sealing lip, wherein a vacuum is generated in the first chamber and overpressure in the second chamber. In this way, the advantages of a vacuum can also be used.

The overpressure can be selected in such a way that despite the vacuum a constant spacing is maintained between the substrate on the one hand and the imprint structure and/or the holder on the other.

### DESCRIPTION OF THE DRAWINGS

Additional advantages and features of the disclosure can be found in the following description and in the attached drawings to which reference is made. In the drawings:

FIG. 1 shows a replication device according to the disclosure, in particular in a loading position,

FIG. 2 shows an additional replication device according to the disclosure in an imprint position,

FIG. 3 shows a chuck for a replication device according to FIGS. 1 and 2, and

FIG. 4 shows an additional chuck for a replication device according to FIGS. 1 and 2.

### DETAILED DESCRIPTION

“A, B and/or C” are to be understood to disclose an arbitrary combination of the alternatives, i.e. the lists are to be read as “A and/or B and/or C”. The same holds true for listings with more than two items.

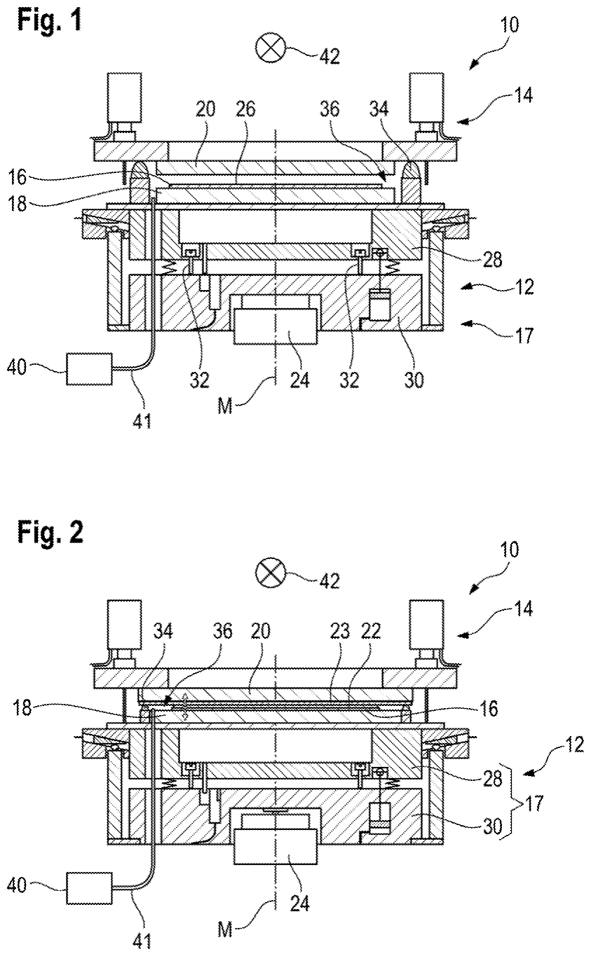

FIGS. 1 and 2 each show a replication device 10 for producing nanostructured and/or microstructured components. By means of the figures, a method of reproducing a structure on a substrate 16 according to the disclosure is elucidated.

The replication device 10 comprises a first assembly 12 and a second assembly 14 that are moveable relative to each other, namely along a central axis M of at least one of the two assemblies 12, 14. The assemblies 12, 14 can thus be brought into an imprint position and into a loading position relative to each other.

In order to be able to receive a substrate 16, the first assembly 12 comprises a chuck 18 on which a substrate 16 is placeable.

The second assembly 14 comprises a holder 20 for an imprint structure 22 that is provided for reproducing a structure on a substrate 16, in particular for a stamp. Such an imprint structure 22 is illustrated in FIG. 2.

In FIG. 1, the replication device 10 is shown in a loading position. In the loading position, both assemblies 12, 14 are at least spaced so far apart from each other that a substrate 16 can be placed in the replication device 10 and/or a substrate 16 positioned in the replication device 10 can be coated, in particular, with an imprint material.

In the imprint position, a substrate 16 positioned in the replication device 10 rests on an imprint structure 22 preferably all over as is shown in FIG. 2.

In the imprint position, the substrate 16 is pressed against the imprint structure 22 with a defined contact force in each case.

The imprint structure 22 is for example formed by a silicon-based polymer, in particular polydimethylsiloxane. This is located, for example, on a glass plate 23, wherein the glass plate 23 and the polymer form in particular a stamp.

Only the first assembly 12 is mounted moveably in the illustrated embodiment. In particular, a lifting device 24 is provided to move the first assembly 12. The second assembly is mounted stationarily. It is however conceivable that both assemblies 12, 14 are mounted moveably.

In order to achieve a good quality of structuring and a uniform reproduction of the imprint structure 22 in an imprint material applied to a substrate 16, it is advantageous if the surface 26 of the substrate 16, in particular the surface 26 of the substrate 16 facing the imprint structure 22, is aligned as parallel as possible to the imprint structure 22. The imprint structure 22 can be immersed as vertically as possible in the imprint material through such a parallel alignment.

As the used substrate 16 does not however comprise necessarily a uniform thickness owing to production tolerances, the surface 26 of a substrate 16 positioned on the chuck 18 can come to rest at an angle greater than zero relative to the imprint structure 22.

To balance such tolerances, the first assembly 12 comprises a wedge error compensation head 17 with a stationary part 30 and a moveable part 28. The moveable part 28 can be aligned relative to the stationary part 30, in particular varied in its inclination, and can comprise the chuck 18. A surface 26 of a substrate 16 supported on the moveable part 28 or on the chuck 18 can thus be aligned parallel to the imprint structure 22.

Before the first assembly is removed from the second assembly 14, i.e. while the assemblies 12, 14 are in the imprint position, the moveable part 28 of the wedge error compensation head of the replication device 10 is locked in place, in particular the moveable part 28 relative to the stationary part 30. For this purpose, brakes 32 are provided which can be used to fix the moveable part 28 relative to the stationary part 30.

The alignment of the substrate 16 on the imprint structure 22 preferably occurs when the first assembly 12 is in the imprint position and the substrate 16 is pressed against the imprint structure using a defined contact force. In this position, it is possible to identify whether the surface 26 of the substrate 16 rests completely on the imprint structure 22. The identification occurs for example using measuring pins and/or sensors which are not shown for the sake of simplicity. If the surface 26 of the substrate 16 is in contact with the imprint structure 22 only in places, a parallelization is necessary, in particular a wedge error compensation.

The wedge error compensation occurs for example with an uncoated substrate 16, i.e. with a substrate 16 on which an imprint material has not been applied. It is however possible to implement a wedge error compensation with a coated substrate 16. This movement can be supported by a compression spring and/or additional pressure cylinders in order to balance the weight of the components and generate the desired pressure.

If the first assembly 12 is removed after the wedge error compensation from the second assembly 14, in particular brought into the loading position, the substrate 16 is to move downwards with the first assembly into the loading position due to gravity. As the imprint structure 22 is usually formed by a sticky, rippled material, the substrate can however remain stuck on the imprint structure 22 and cannot separate from the imprint structure 22 uniformly. Thus, a previously set wedge error compensation can be lost, i.e. the fixed position of the moveable part 28 of the wedge error compensation head 17 relative to the stationary part 30 of the wedge error compensation head 17 and relative to the imprint structure 22.

To enable the substrate 16 to be detached uniformly from the imprint structure 22, the first assembly 12 and the second assembly 14 are actively moved away from each other by means of separation force after the substrate 16 is brought into contact with the imprint structure 22.

To this end, at least one sealing lip 34 is located on one of the two assemblies 12, 14, in the shown embodiment on the first assembly 12, said sealing lip facing the other one of the two assemblies 12, 14, in the shown embodiment the second assembly 14.

In the imprint position 22, the sealing lip 34 touches the second assembly 14, wherein the sealing lip 34 surrounds the chuck 18 and/or the holder 20 radially, in particularly completely radially.

In this way, a sealed overpressure chamber 36 between both assemblies 12, 14 is limited by the sealing lip in the imprint position.

In the embodiment of the replication device 10 shown in FIG. 1, the sealing lip 34 rests on the second assembly 14 outside the holder 20 radially.

In FIG. 2, an additional embodiment of the replication device 10 is illustrated, in which the sealing lip 34 rests directly on the holder 20 or on the glass plate 23 if an imprint structure 22 is held in the holder 20.

The sealing lip 34 is preferably inflatable, in particular to form a sealed overpressure chamber 36. Through the enlargement of the sealing lip 34 during inflation, the sealing lip 34 can also help to actively force the first assembly 12 and the second assembly 14 apart by means of a separation force. For example, the sealing lip 34 can be inflated if the first assembly 12 is in the imprint position, in particular if the sealing lip 34 is already in contact with the second assembly 14.

Both assemblies 12, 14 as well as the substrate 16 and the imprint structure 22 are forced apart by the overpressure and/or the sealing lip 34, for example with a force of up to 900 N.

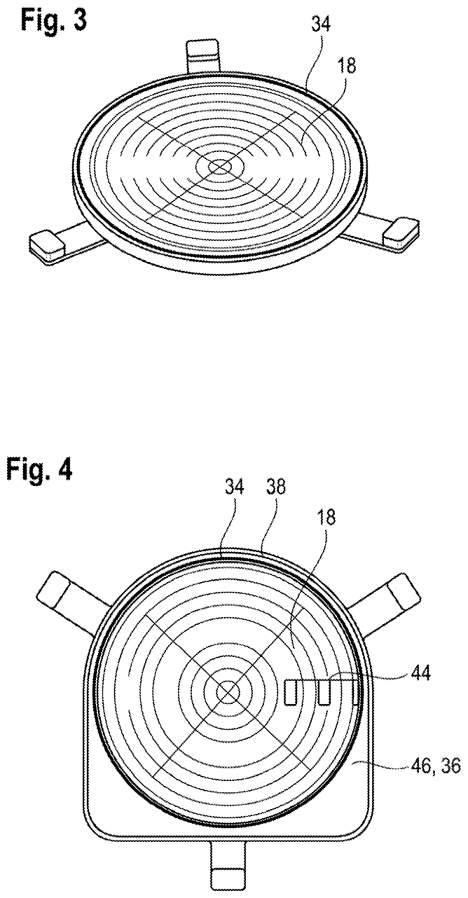

For example in FIG. 3, a chuck 18 is shown with a sealing lip 34 located on the chuck 18 that is annular or circular seen in top view on the chuck. The sealing lip 34 has a constant profile in the shown embodiment. The profile of the sealing lip 34 can however vary. In particular, the height of the sealing lip 34 can vary.

It is also conceivable that several sealing lips 34, 38 are provided, for example, two sealing lips 34, 38, wherein one sealing lip 38 radially surrounds, preferably completely surrounds, the other one of the two sealing lips 34. This is shown in FIG. 4 which shows a top view of the first assembly 12 in an alternative embodiment. In this embodiment, the first assembly 12 is provided with two sealing lips 34, 38 that surround the chuck 18.

A first chamber 44 can be formed using the inner, first sealing lip 34 and a second chamber 46 can be formed using the outer, second sealing lip 38.

Both chambers 44, 46 are preferably separated from each other in a pressure-tight manner when both sealing lips 34, 38 are completely inflated. As a result, different pressure ratios can exist in both chambers 44, 46. For example, the first chamber 44 can be vacuum chamber and the second chamber 46 an overpressure chamber.

The first sealing lip 34 is an annular sealing lip 34 and the second sealing lip 38 is a portal-shaped sealing lip 38. “Portal-shaped” means within the scope of this disclosure that the contour of the sealing lip 38 has the contour of a rectangle with a semi-circle added to it.

The sealing lips 34, 38 can be inflated separately from each other both simultaneously and at different times.

For example, the first sealing lip 34 of the replication device 10 can be inflated initially and deflated at a later time and the second sealing lip 38 can be inflated before, during or after deflating the first sealing lip 34.

According to another alternative embodiment, it is possible to only provide one portal-shaped sealing lip 38.

It is also conceivable in another alternative embodiment that one of the two sealing lips 34, 38 is located on the first assembly 12 and the other one of the two sealing lips 34, 38 is located on the second assembly 14.

If the assemblies 12, 14 are in the imprint position, overpressure can be generated in the overpressure chamber 36, said overpressure serves to force the first assembly 12 and the second assembly 14 and/or the substrate 16 and the imprint structure 22 actively apart. To this end, an overpressure source is provided that is fluidly connected with the pressure chamber 36 via a pressure line 41.

The overpressure in the overpressure chamber 36 causes, so to speak, the substrate 16 to separate, in particular blow off, from the imprint structure 22. The overpressure can namely spread into the small cavities that may be present between the substrate 16 and the imprint structure 22 and are open towards the overpressure chamber 36. Such cavities may be present due to the geometry of the imprint structure 22. In addition, the imprint structure 22 can be compressed to a certain extent by the overpressure so that an area is formed between the imprint structure 22 and substrate 16, in said area overpressure may also exist.

Moreover, the imprint structure 22 is forced against the holder 20 and the substrate 16 is forced against the chuck 18 by the overpressure. If the assemblies 12, 14 move from the imprint position into the loading position, thus away from each other, this ensures that the substrate 16 does not separate from the chuck 18 and the imprint structure 22 does not separate from the holder 20. This prevents the substrate 16 from remaining adhered to the imprint structure 22 and potentially being lifted from the chuck 18, potentially resulting in the loss of a previously set wedge error compensation.

A pressure in the overpressure chamber 36 can also be regulated in the imprint position in order to keep a constant gap between the substrate 16 and the imprint structure 22.

To enable a particularly precise wedge error compensation, the substrate 16 can be moved in an uncoated state from the loading position into the imprint position repeatedly. This may occur by means of repeated inflating or at least partial deflation of the sealing lips 34, 38 and/or overpressure chamber 36.

In the case of the uncoated substrate 16 being moved from the loading position into the imprint position repeatedly, the substrate 16 can be aligned to the imprint structure 22 in each case with contact force of differing strength, in particular with contact force that decreases with each repeated alignment.

The contact force is created by the lifting device 24.

After the wedge error compensation is completed, the substrate 16 and/or the imprint structure 22 are coated with an imprint material. Then, the substrate is moved in a coated state together with the first assembly 12 into the imprint position and forced onto the imprint structure 22 with a defined contact force in order to structure the coating by means of the imprint structure. This state is shown in FIG. 2.

After the structuring, the imprint material is exposed to ultraviolet light in order to cure the imprint material. The exposure can occur through the holder 20 and the imprint structure 22. The replication device has an exposure device 42 to perform the exposure.

The curing occurs while the assemblies 12, 14 are still in the imprint position.

Subsequently, overpressure is generated in the overpressure chamber 36 once more in order to separate the finished substrate 16 from the imprint structure 22. In doing so, the overpressure may be greater than the overpressure generated in the wedge error compensation. After the imprint material has been cured, the substrate 16 namely adheres more strongly to the imprint structure 22 as in the wedge error compensation.

The detachment of the substrate 16 from the imprint structure 22 occurs basically according to the same principle as the detachment of the uncoated substrate 16 in wedge error compensation. In particular, an overpressure can force the substrate 16 and the imprint structure 22 actively apart by spreading the overpressure into the cavities between the substrate 16 and the imprint structure 22 and/or by compressing the imprint structure 22 to a certain extent and/or forcing the imprint structure 22 against the holder 20 and the substrate 16 against the chuck 18 as a result of the overpressure.

In each case, the overpressure should be sufficiently great in order to force the substrate 16 and the imprint structure 22 apart in both a coated and uncoated state.

In the event that two sealing lips 34, 38 are provided, both chambers 44, 46 are formed by inflating both sealing lips 34, 38 in the imprint position.

The second chamber 46 forms the overpressure chamber 36 previously described and the first chamber 44 is fluidly connected with a vacuum source and a vacuum is generated in the first chamber 44.

The substrate is located in the first chamber 44 completely and the vacuum causes the imprint material to be degassed as well as removes bubble from the imprint material and between the imprint structure, the imprint material and the substrate. The vacuum can also support the contacting process.

The overpressure in the overpressure chamber 36 is thus selected so that despite the vacuum a constant spacing is maintained between the substrate on the one hand and the imprint structure and/or the holder on the other.

1. A replication device for producing at least one of nanostructured and microstructured components with two assemblies that are moveable in relation to each other, wherein the first assembly comprises a chuck for receiving a substrate and a second assembly a holder for an imprint structure,
wherein the assemblies are moveable between an imprint position and a loading position relative to each other, and
wherein at least a sealing lip is located on one of the two assemblies, said sealing lip facing the other one of the two assemblies and contacting the other one of the two assemblies in the imprint position and radially surrounding at least one of the chuck and the holder, wherein a sealed overpressure chamber between the two assemblies is limited by the sealing lip in the imprint position.

2. The replication device according to claim 1, wherein the sealing lip is inflatable.

3. The replication device according to claim 1, wherein the sealing lip is annular or portal-shaped seen in top view on the corresponding assembly.

4. The replication device according to claim 2, wherein two sealing lips are provided that are inflatable separately from each other, wherein one of the sealing lips radially surrounds the other.

5. The replication device according to claim 4, wherein a first chamber is formed in part by the inner sealing lip and a second chamber is formed in part by the outer sealing lip, wherein the first chamber is a vacuum chamber and the second chamber an overpressure chamber.

6. The replication device according to claim 1, wherein the first assembly forms a wedge error compensation head comprising a stationary part and a moving part.

7. The replication device according to claim 1, wherein the replication device comprises a pressure source for generating at least one of overpressure in the sealing lip and the overpressure chamber.

8. The replication device according to claim 1,
wherein the replication device comprises an exposure device for curing at least one of microstructuring and nanostructuring formed on a substrate.

9. A method for reproducing a structure on a substrate comprising the following steps:
placing a substrate on a first assembly of a replication device and placing an imprint structure on a second assembly of the replication device;
moving the assemblies relative to each other from a loading position into an imprint position, wherein a surface of the substrate facing the imprint surface or a coating of the substrate comes into in contact with imprint structure all over in the imprint position; and
actively moving the first assembly and the second assembly after the substrate has been brought into contact with the imprint structure, away from each other through an application of a separation force.

10. The method according to claim 9, wherein an inflatable sealing lip of the replication device that surrounds the substrate radially is inflated when the first assembly is in the imprint position so that a sealed pressure chamber is formed.

11. The method according to claim 10, wherein the first assembly and the second assembly are pressed apart when inflating the sealing lip so that the sealing lip generates the separation force.

12. The method according to claim 9, wherein the substrate is initially placed in an uncoated state on the replication device and moved together with the first assembly into the imprint position in order to parallelize the substrate relative to the imprint structure.

13. The method according to claim 9, wherein at least one of the substrate and the imprint structure is coated with an imprint material and then moved in a coated state together with the first assembly into the imprint position to structure the coating by means of the imprint structure.

14. The method according to claim 9, wherein an overpressure is generated in the imprint position in the sealed pressure chamber by an overpressure source in order to attain the active movement so that the separation force is generated by the overpressure source in connection with the sealing lip.

15. The method according to claim 14, wherein the overpressure is sufficiently great to force the imprint structure and the substrate apart if the substrate is uncoated or coated.

16. The method according to claim 10, wherein the substrate is moved repeatedly in an uncoated state from the loading position into the imprint position.

17. The method according to claim 16, wherein in the case of the uncoated substrate being moved repeatedly from the loading position into the imprint position, the substrate is aligned each time on the imprint structure with a contact force of differing strength.

18. The method according to claim 9, wherein pressure in the overpressure chamber is regulated in the imprint position in order to keep a constant gap between the substrate and the imprint structure.

19. The method according to claim 9, wherein a first sealing lip of the replication device is initially inflated and the first sealing lip is deflated at a later time and another sealing lip that is different from the first sealing lip is inflated.

20. The method according to claim 9, wherein a first chamber is formed using the first sealing lip and the second chamber is formed using the second sealing lip, wherein a vacuum is generated in the first chamber and overpressure in the second chamber.
